(19) United States
(12) Patent Application Publication
(10) Pub. No.: US 2026/0090407 A1
(43) Pub. Date: Mar. 26, 2026

(54) Semiconductor Devices and Methods for Manufacturing Thereof

(71) Applicant: Infineon Technologies AG, Neubiberg (DE)

(72) Inventors: Guey Yong Chee, Batu Berendam, MEL (MY); Thai Kee Gan, Melaka Tengah (MY); Chee Yang Ng, Muar (MY)

(21) Appl. No.: 19/328,165

(22) Filed: Sep. 14, 2025

(30) Foreign Application Priority Data
Sep. 23, 2024 (DE) 102024127473.5

(51) Int. Cl. H01L 23/495; H01L 25/00; H01L 25/065

(52) U.S. Cl. CPC H10W 70/468; H10W 70/429; H10W 70/465; H10W 70/466; H10W 90/00; H10W 90/811; H10W 90/22; H10W 90/288

(57) ABSTRACT

A semiconductor device includes a chip carrier, a first power chip arranged above a mounting surface of the chip carrier, a laminate arranged above a top surface of the first power chip facing away from the chip carrier, and a first logic chip configured to drive the first power chip and arranged above a top surface of the laminate facing away from the chip carrier. The first power chip and the first logic chip are electrically coupled via an electrical wiring of the laminate.

### TECHNICAL FIELD

The present disclosure relates to semiconductor devices and methods for manufacturing semiconductor devices.

### BACKGROUND

Semiconductor chips and other electronic components included in semiconductor devices may be interconnected by wires which may result in high resistance and/or high inductance values. In addition, usage of a large number of wires may increase production costs and lead to high complexity of the devices. At the same time, semiconductor chips included in semiconductor devices are getting smaller and smaller which may result in a reduced size of chip contacts and smaller distances between the chip contacts.

Manufacturers and developers of semiconductor devices are constantly striving to improve their products. In view of the above, it may be desirable to provide semiconductor devices at least partially addressing the above identified issues. In addition, it may be desirable to provide simple and cost efficient methods for manufacturing such semiconductor devices.

### SUMMARY

An aspect of the present disclosure relates to a semiconductor device. The semiconductor device comprises a chip carrier, a first power chip arranged above a mounting surface of the chip carrier, a laminate arranged above a top surface of the first power chip facing away from the chip carrier, and a first logic chip configured to drive the first power chip and arranged above a top surface of the laminate facing away from the chip carrier. The first power chip and the first logic chip are electrically coupled via an electrical wiring of the laminate.

A further aspect of the present disclosure relates to a method for manufacturing a semiconductor device. The method comprises providing a chip carrier, arranging a first power chip above a mounting surface of the chip carrier, arranging a laminate above a top surface of the first power chip facing away from the chip carrier, and arranging a first logic chip above a top surface of the laminate facing away from the chip carrier. The first power chip and the first logic chip are electrically coupled via an electrical wiring of the laminate.

Those skilled in the art will recognize additional features and advantages upon reading the following detailed description, and upon viewing the accompanying drawings.

### BRIEF DESCRIPTION OF THE DRAWINGS

Devices and methods in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1 schematically illustrates a sectional side view of a semiconductor device 100 in accordance with the disclosure.

FIG. 2 includes FIGS. 2A to 2C schematically illustrating an assembly of a semiconductor device 200 in accordance with the disclosure.

FIG. 3 schematically illustrates a sectional side view of a semiconductor device 300 in accordance with the disclosure.

FIG. 4 includes FIGS. 4A to 4C schematically illustrating an assembly of a semiconductor device 400 in accordance with the disclosure.

FIG. 5 includes FIGS. 5A to 5C schematically illustrating a sectional side view, a top view and a circuit diagram of a semiconductor device 500 in accordance with the disclosure.

FIG. 6 includes FIGS. 6A to 6C schematically illustrating a sectional side view, a top view and a circuit diagram of a semiconductor device 600 in accordance with the disclosure.

FIG. 7 illustrates a flowchart of a method for manufacturing a semiconductor device in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

Referring now to FIG. 1, a semiconductor device 100 in accordance with the disclosure may include a chip carrier 2 and a power chip 4 arranged above a mounting surface 6 of the chip carrier 2. The semiconductor device 100 may further include a laminate 8 arranged above a top surface of the power chip 4 facing away from the chip carrier 2. In addition, the semiconductor device 100 may include a logic chip 10 configured to drive the power chip 4 and arranged above a top surface of the laminate 8 facing away from the chip carrier 2. The power chip 4 and the logic chip 10 may be electrically coupled via an electrical wiring 12 of the laminate 8.

In the illustrated example, the chip carrier 2 may be a leadframe including a diepad 14 and a plurality of leads (or lead fingers or pins) 16A to 16C. The leads 16A to 16C may be arranged at a periphery of the diepad 14. In the shown case, the end portions of the leads 16A to 16C may be exemplarily bent downwards. In the illustrated side view, only two leads 16A and 16B may be visible due to the chosen perspective. The lead 16C may be arranged behind the lead 16B and may thus be obscured. It is to be understood that the leadframe 2 may include additional leads which may be hidden behind the visible ones. The leadframe 2 (i.e. the diepad 14 and the leads 16A to 16C) may include or may be made of a metal or a metal alloy. For example, the leadframe 2 may include a core material including at least one of copper, copper alloy, aluminum, aluminum alloy, or the like. Optionally, the leadframe 2 may be plated with at least one plating material which may, for example, include at least one of nickel, nickel-phosphorous, nickel-nickel-phosphorous, copper, silver, or the like.

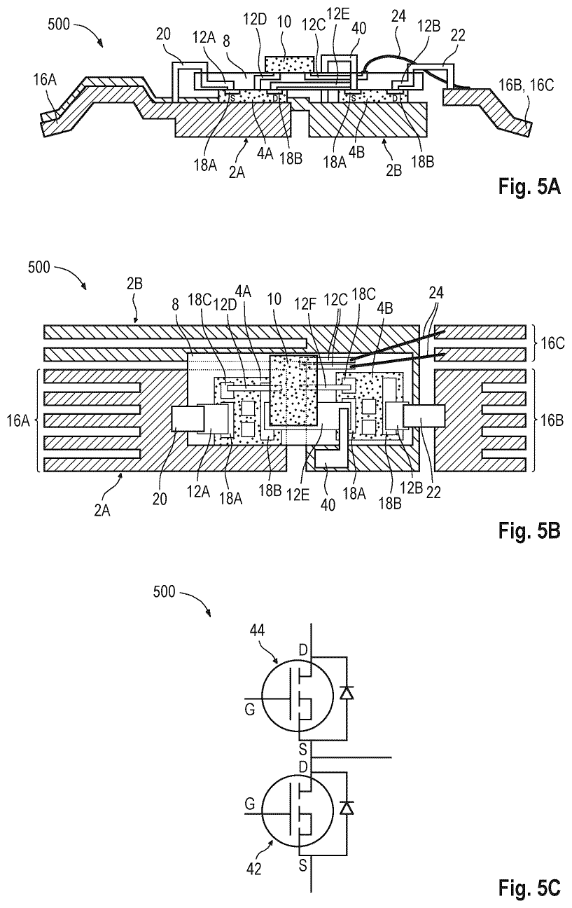

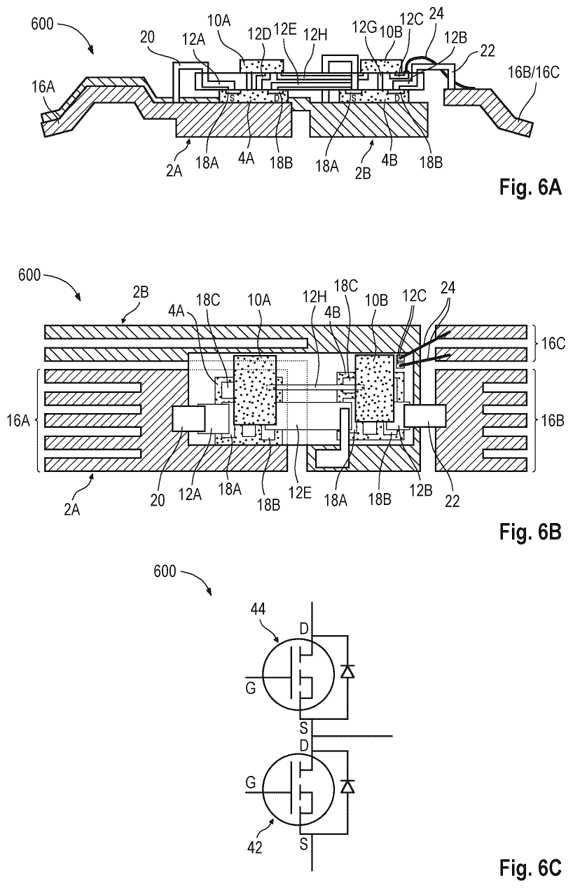

The semiconductor chips 4 and 10 may be manufactured from an elemental semiconductor material (e.g. Si) or from a wide band gap semiconductor material or a compound semiconductor material (e.g. SiC, GaN, SiGe, GaAs). In a non-limiting example, the power chip 4 may be a GaN-chip, while the logic chip 10 may be a Si-chip. In the illustrated example, the semiconductor device 100 may include a power chip 4 and a logic chip 10. However, it is to be understood that the semiconductor device 100 may include one or more additional semiconductor chips depending on the considered application. Examples of semiconductor devices in accordance with the disclosure including more than two semiconductor chips are described below in connection with FIGS. 5 and 6. It is to be understood that throughout this description, the terms “chip”, “semiconductor chip”, “die”, “semiconductor die” may be used interchangeably.

The semiconductor chip 4 may be a power semiconductor chip. In this context, the term “power semiconductor chip” may refer to a semiconductor chip providing at least one of high voltage blocking or high current-carrying capabilities. A power semiconductor chip may be configured for high currents having a maximum current value of a few Amperes, such as e.g. 10 A, or a maximum current value of up to or exceeding 100 A. Similarly, voltages associated with such current values may have values of a few Volts to a few tens or hundreds or even thousands of Volts, such as e.g. about 1200V, about 1600V, about 2400V, or the like. Power semiconductor chips may be used in any kind of power application like e.g. MOSFETs (Metal Oxide Semiconductor Field Effect Transistors), HEMTs (High Electron Mobility Transistors), half bridge circuits, power modules including a gate driver, etc. For example, power semiconductor chips may include or may be part of a power device like e.g. a power MOSFET, an LV (low voltage) power MOSFET, a power IGBT (Insulated Gate Bipolar Transistor), a power diode, a power HEMT, a superjunction power MOSFET, or the like.

In the illustrated example, the power chip 4 may particularly correspond to a lateral power semiconductor chip including electrical contacts 18A, 18B arranged on the top surface of the power chip 4. In a non-limiting example, the power chip 4 may be a lateral GaN power chip. In the illustrated side view, only two electrical contacts 18A, 18B are shown due to the chosen perspective, but the power chip 4 may include additional electrical contacts depending on the specific chip type. In a non-limiting example, the power chip 4 may correspond to a power transistor chip. In some examples, the electrical contacts of the power chip 4 may include a gate contact, a drain contact and a source contact. In other examples, the electrical contacts of the power chip 4 may include a base contact, a collector contact and an emitter contact.

The semiconductor chip 10 may be a logic semiconductor chip. In particular, the logic chip 10 may be a driver chip. In this context, the logic chip 10 may include driver circuits configured to drive the power chip 4. A driver circuit may be configured to drive one or more electronic components, for example a high-power transistor that may be included in the device. The driven components may be voltage driven or current driven. For example, Power MOSFETs, IGBTs, or the like, may be voltage driven switches, since their insulated gate may particularly behave like a capacitor. Conversely, switches such as triacs (triode for alternating current), thyristors, bipolar transistors, a PN diode, or the like, may be current driven. In one example, driving a component including a gate electrode may include applying different voltages to the gate electrode, e.g. in form of turn-on and turn-off switching wave forms. In a further example, a driver circuit may be used to drive a direct driven circuit.

In some example, the semiconductor device 100 may further include a controller chip (not illustrated) which may include a control circuit configured to control one or more driver chips of the device. In one example, the control circuit may simultaneously control drivers of multiple direct driven circuits. For example, a half bridge circuit including two direct driven circuits may thus be controlled by the controller chip.

The laminate 8 may, for example, correspond to a multilayer laminate which may include a plurality of metal layers that may particularly extend in the horizontal direction. In addition, the multilayer laminate may include a dielectric material arranged between the metal layers. Stated differently, the metal layers may be embedded in the dielectric material. The dielectric material may be configured to electrically isolate the metal layers from each other. Furthermore, the multilayer laminate may include a plurality of electrical via connections that may particularly extend in the vertical direction. The electrical via connections may be configured to electrically couple metal layers arranged on different levels with respect to the vertical direction.

The electrical wiring 12 of the laminate 8 may be at least partially arranged inside the laminate 8, but may also include portions (such as e.g. electrical tracks) arranged on the top surface and/or the bottom surface of the laminate 8. In the illustrated example, multiple portions 12A to 12D of the electrical wiring 12 are shown, but it is to be understood that the electrical wiring 12 may also include additional wiring portions which are not shown for the sake of simplicity. For example, the portions 12A, 12B and 12D may provide an electrical connection between the top surface and the bottom surface of the laminate 8, while the portion 12C may provide an electrical connection between two different locations on the top surface of the laminate 8.

The semiconductor device 100 may include a first electrical coupling element 20 electrically coupling the top surface of the laminate 8 and a first portion of the chip carrier 2. In the illustrated example, the first electrical coupling element 20 may include or may correspond to a first clip electrically coupling the top surface of the laminate 8 and the diepad 14. The diepad 14 may be electrically connected to the first lead 16A. In an example, the diepad 14 and the first lead 16A may be formed as a single piece. The first electrical coupling element 20 may be electrically coupled to the first electrical contact 18A of the power chip 4 via a first portion 12A of the electrical wiring 12 of the laminate 8. In the illustrated example, the first clip 20 may e.g. be electrically coupled to a source contact or an emitter contact 18A of the power transistor chip 4 via the first portion 12A of the electrical wiring 12. The source contact or emitter contact 18A of the power transistor chip 4 may thus be electrically coupled to and/or electrically accessible via the first lead 16A which may thus be referred to as source or emitter lead. In a similar fashion, the first clip 20 may be referred to as source or emitter clip.

The semiconductor device 100 may include a second electrical coupling element 22 electrically coupling the top surface of the laminate 8 and a second portion of the chip carrier 2. In the illustrated example, the second electrical coupling element 22 may include or may correspond to a second clip electrically coupling the top surface of the laminate 8 and the second lead 16B of the plurality of leads of the leadframe 2. The second electrical coupling element 22 may be electrically coupled to the second electrical contact 18B of the power transistor chip 4 via a second portion 12B of the electrical wiring 12 of the laminate 8. In the illustrated example, the second clip 22 may e.g. be electrically coupled to a drain contact or a collector contact 18B of the power transistor chip 4 via the second portion 12B of the electrical wiring 12. The drain contact or collector contact 18B of the power transistor chip 4 may thus be electrically coupled to and/or electrically accessible via the second lead 16B which may thus be referred to as drain or collector lead. In a similar fashion, the second clip 22 may be referred to as drain or collector clip.

The semiconductor device 100 may include a third electrical coupling element 24 electrically coupling the top surface of the laminate 8 and a third portion of the chip carrier 2. In the illustrated example, the third electrical coupling element 24 may include or may correspond to a wire electrically coupling the top surface of the laminate 8 and the third lead 16C of the plurality of leads. In the side view of FIG. 1, the third lead 16C may be arranged behind the second lead 16B and may thus be not visible. The third electrical coupling element 24 may be electrically coupled to an electrical contact of the logic chip 10 via a third portion 12C of the electrical wiring 12 of the laminate 8.

The logic chip 10 may be electrically coupled to a gate contact or a base contact of the power transistor chip 4 via a fourth portion 12D of the electrical wiring 12 of the laminate 8. The fourth portion 12D of the electrical wiring may extend from the top surface of the laminate 8 to the bottom surface of the laminate 8. In the illustrated non-limiting case, the fourth portion 12D is exemplarily illustrated by two vertical through connections which may differ in other examples. The gate contact or base contact of the power transistor chip 4 may be electrically coupled to and/or electrically accessible via the third lead 16C which may thus be referred to as gate or base lead.

In the illustrated example, the drain or collector lead 16B and the gate or base lead 16C may be arranged at the right side of the arrangement, while the source or emitter lead 16A may be arranged on the opposite left side. It is to be understood that in further examples, the positions of the leads 16A and 16B may be exchanged, i.e. the source or emitter lead 16A and the gate or base lead 16C may arranged at a same side of the arrangement, while the drain or collector lead 16B may be arranged at the opposite side.

As can be seen from the illustrated example, an electrical coupling between the power chip 4 and the logic chip 10 may be particularly provided exclusively via the electrical wiring 12 of the laminate 8. No further electrical connections arranged outside of the laminate 8 may be required for an electrical connection between the semiconductor chips 4 and 10.

The semiconductor device 100 may outperform conventional semiconductor devices in various ways and may provide various technical features as described in the following.

As previously described, the electrical contacts 18 of the power chip 4 may be electrically connected to the electrical wiring 12 of the laminate 8. Due to a usage of the laminate 8, the electrical contacts 18 (in particular the source and drain contacts of the power chip 4) may be fully utilized and may have a maximum contact to the laminate 8 such that an increased electrical performance of the semiconductor device 100 may be provided.

Conventional semiconductor devices may employ wires as electrical coupling elements, which may have high resistance and high inductance. In addition, a high number of wires may increase the complexity of the arrangement and production costs due to low UPH (Units Per Hour). In contrast to this, in a semiconductor device in accordance with the disclosure, a large number of wires may be replaced by few clips such that an electrical performance of the semiconductor device may be optimized.

The power chip 4 and the logic chip 10 may be arranged on opposite sides of the same laminate 8. This way, the logic chip 10 may be arranged very close to the power chip 4 and a very short electrical connection between the power chip 4 and the logic chip 10 may be provided. Parasitics between the power chip 4 and the logic chip 10 may be reduced.

The laminate 8 may provide a support and a mounting surface for the logic chip 10 for space savings such that the dimensions of the semiconductor device 100 may be reduced and a more compact solution may be provided.

The electrical wiring 12 of the laminate 8 may provide a spreading of the electrical contacts 18 of the power chip 4 on the top surface of the laminate 8. By using the laminate 8, it is possible to extend the distance between the source pad and the drain pad of the power chip 4 to a bigger distance on the top surface of the laminate 8. Stated differently, a distance between the source or emitter contact of the power transistor chip 4 and the drain or collector contact of the power transistor chip 4 may be smaller than a distance between a first contact point 26A between the first clip 20 and the top surface of the laminate 8 and a second contact point 26B between the second clip 22 and the top surface of the laminate 8.

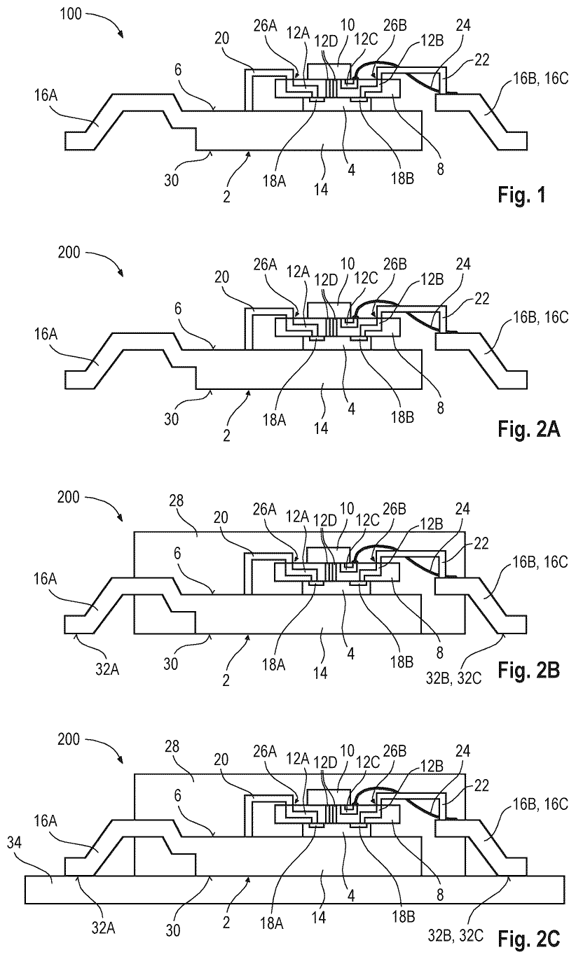

Referring now to FIGS. 2A to 2C, an assembly of a semiconductor device 200 in accordance with the disclosure is schematically illustrated. In FIG. 2A, the semiconductor device 200 may be provided. The semiconductor device 200 may be similar to the semiconductor device 100 of FIG. 1 and may include some or all features of it. All comments made in connection with FIG. 1 may also hold true for FIG. 2A.

In FIG. 2B, the arrangement of FIG. 2A may be at least partially encapsulated in an encapsulation material 28. The encapsulation material 28 may include or may be made of at least one of an epoxy, a filled epoxy, a glass fiber filled epoxy, an imide, a thermoplast, a thermoset polymer, a polymer blend, a laminate, a mold compound, or the like. Various techniques may be used for encapsulating components in the encapsulation material 28, for example at least one of compression molding, injection molding, powder molding, liquid molding, map molding, laminating, or the like. The leads 16A to 16C may at least partially protrude out of the encapsulation material 28 such that the power chip 4 and the logic chip 10 may be electrically accessible via the leads 16A to 16C. After the encapsulation process, a surface 30 of the chip carrier 2 opposite to the mounting surface 6 of the chip carrier 2 may be exposed and coplanar with surfaces 32A to 32C of the leads 16A to 16C.

In FIG. 2C, the arrangement of FIG. 2B may be mechanically and electrically coupled to a printed circuit board 34. For example, the exposed surfaces 32A to 32C of the leads 16A to 16C may be soldered to electrical contacts on the top surface of the printed circuit board 34.

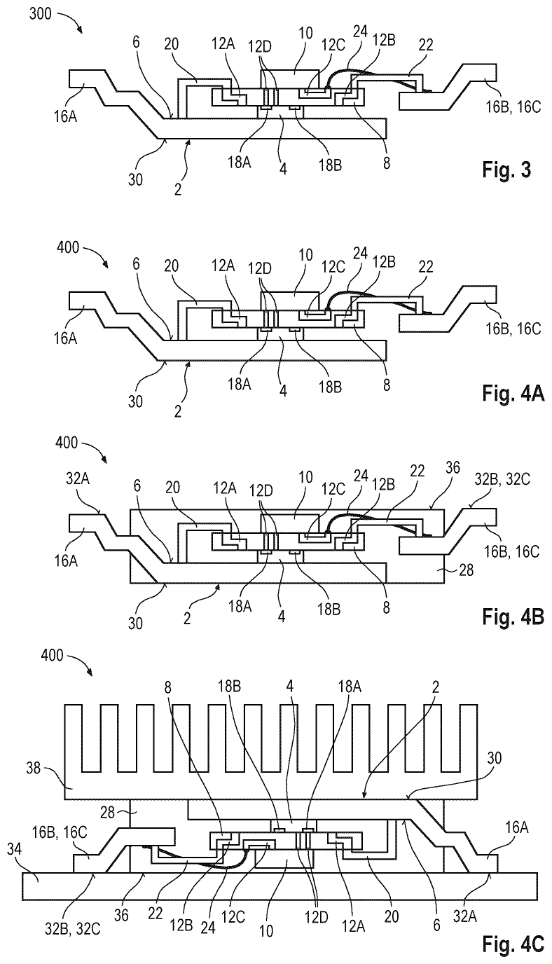

Referring now to FIG. 3, a further semiconductor device 300 in accordance with the disclosure is shown. For example, the semiconductor device 300 may include some or all features of the semiconductor device 100 of FIG. 1. In contrast to the example of FIG. 1, the end portions of the leads 16A to 16C of the semiconductor device 300 may extend in an upward direction.

Referring now to FIGS. 4A to 4C, an assembly of a semiconductor device 400 in accordance with the disclosure is schematically illustrated. In FIG. 4A, the semiconductor device 400 may be provided. For example, the semiconductor device 400 may include some or all features of the semiconductor device 300 of FIG. 3.

In FIG. 4B, the arrangement of FIG. 4A may be at least partially encapsulated in an encapsulation material 28. The encapsulation material 28 may be similar to the encapsulation material 28 previously described in connection with FIG. 2. The leads 16A to 16C may at least partially protrude out of the encapsulation material 28 such that the power chip 4 and the logic chip 10 may be accessible via the leads 16A to 16C. After the encapsulation process, a surface 30 of the chip carrier 2 opposite to the mounting surface 6 of the chip carrier 2 may be exposed. The leads 16A to 16C may be bent or may extend in a direction away from the exposed surface 30 of the chip carrier 2. A top surface 36 of the encapsulation material 28 may be substantially coplanar with top surfaces 32A to 32B of the leads 16A to 16C.

In FIG. 4C, the arrangement of FIG. 4B may be turned and may be mechanically and electrically coupled to a printed circuit board 34. For example, the surfaces 32A to 32C of the leads 16A to 16C may be soldered to electrical contacts on the top surface of the printed circuit board 34. Furthermore, an optional heatsink 38 may be mounted on the exposed surface 30 of the chip carrier 2. In one example, the heatsink 38 may be soldered to the exposed surface 30 of the chip carrier 2.

Referring now to FIG. 5, a further semiconductor device 500 in accordance with the disclosure is illustrated. More particular, FIG. 5A shows a sectional side view of the semiconductor device 500, FIG. 5B shows a top view of the semiconductor device 500, and FIG. 5C shows a circuit diagram of the semiconductor device 500. The semiconductor device 500 may include some or all features of previously described semiconductor devices.

The semiconductor device 500 may include a chip carrier 2 having a first portion 2A and a second portion 2B. The chip carrier portions 2A and 2B may be separate from each other. A first power transistor chip 4A may be arranged on a mounting surface of the first carrier portion 2A, while a second power transistor chip 4B may be arranged on a mounting surface of the second carrier portion 2B. In the illustrated example, each of the first and second power chips 4A, 4B may be a lateral power chip including a source contact 18A, a drain contact 18B and a gate contact 18C arranged on the top surface of the respective chip. A laminate 8 may be arranged on the top surfaces of the power chips 4A, 4B. Furthermore, a logic chip 10 may be arranged on the top surface of the laminate 8. Similar to previous examples, the laminate 8 may include an electrical wiring 12 for interconnecting the components of the semiconductor device 500.

The first power chip 4A may be electrically coupled to the second power chip 4B and to the logic chip 10 via the electrical wiring 12 of the laminate 8. The source contact 18A of the first power chip 4A may be electrically connected to first leads 16A of the first carrier portion 2A via a portion 12A of the electrical wiring 12 and a first clip 20. The first leads 16A may be referred to as source leads. The drain contact 18B of the first power chip 4A may be electrically connected to the source contact 18A of the second power chip 4B via a portion 12E of the electrical wiring 12. The gate contact 18C of the first power chip 4A may be electrically connected to the logic chip 10 via a portion 12D of the electrical wiring 12.

The second power chip 4B may be electrically coupled to the first power chip 4A and to the logic chip 10 via the electrical wiring 12 of the laminate 8. The source contact 18A of the second power chip 4B may be electrically connected to the drain contact 18B of the first power chip 4A via the portion 12E of the electrical wiring 12. The drain contact 18B of the second power chip 4B may be electrically connected to second leads 16B via a portion 12B of the electrical wiring 12 and a second clip 22. The second leads 16B may be referred to as drain leads. The gate contact 18C of the second power chip 4B may be electrically connected to the logic chip 10 via a portion 12F of the electrical wiring 12. The logic chip 10 may be electrically connected to third leads 16C via portions 12C of the electrical wiring and wires 24.

The first power chip 4A may form part of a low side switch of a half bridge circuit, while the second power chip 4B may form part of a high side switch of the half bridge circuit. An exemplary circuit diagram of a half bridge circuit including a low side switch 42 and a high side switch 44 is shown in FIG. 5C. The logic chip 10 may be configured to drive the first power chip 4A and the second power chip 4B.

Referring now to FIG. 6, a further semiconductor device 600 in accordance with the disclosure is illustrated. More particular, FIG. 6A shows a sectional side view of the semiconductor device 600, FIG. 6B shows a top view of the semiconductor device 600, and FIG. 6C shows a circuit diagram of the semiconductor device 600. The semiconductor device 600 may include some or all features of previously described semiconductor devices.

The semiconductor device 600 may include a chip carrier having a first portion 2A and a second portion 2B. The chip carrier portions 2A and 2B may be separate from each other. A first power transistor chip 4A may be arranged on a mounting surface of the first carrier portion 2A, while a second power transistor chip 4B may be arranged on a mounting surface of the second carrier portion 2B. In the illustrated example, each of the first and second power chips 4A, 4B may be a lateral power chip including a source contact 18A, a drain contact 18B and a gate contact 18C arranged on the top surface of the respective chip. A laminate 8 may be arranged on the top surfaces of the power chips 4A, 4B. Furthermore, a first logic chip 10A and a second logic chip 10 may be arranged on the top surface of the laminate 8. Similar to previous examples, the laminate 8 may include an electrical wiring 12 for interconnecting the components of the semiconductor device 600.

The first power chip 4A may be electrically coupled to the second power chip 4B and to the first logic chip 10A via the electrical wiring 12 of the laminate 8. The source contact 18A of the first power chip 4A may be electrically connected to first leads 16A of the first carrier portion 2A via a portion 12A of the electrical wiring 12 and a first clip 20. The first leads 16A may be referred to as source leads. The drain contact 18B of the first power chip 4A may be electrically connected to the source contact 18A of the second power chip 4B via a portion 12E of the electrical wiring 12. The gate contact 18C of the first power chip 4A may be electrically connected to the first logic chip 10A via a portion 12D of the electrical wiring 12.

The second power chip 4B may be electrically coupled to the first power chip 4A and to the second logic chip 10B via the electrical wiring 12 of the laminate 8. The source contact 18A of the second power chip 4B may be electrically connected to the drain contact 18B of the first power chip 4A via the portion 12E of the electrical wiring 12. The drain contact 18B of the second power chip 4B may be electrically connected to second leads 16B via a portion 12B of the electrical wiring 12 and a second clip 22. The second leads 16B may be referred to as drain leads. The gate contact 18C of the second power chip 4B may be electrically connected to the second logic chip 10B via a portion 12G of the electrical wiring 12. The second logic chip 10B may be electrically connected to third leads 16C via a portion 12C of the electrical wiring 12 and wires 24.

The first logic chip 10A may be electrically coupled to the second logic chip 10B via a portion 12H of the electrical wiring 12 of the laminate 8. The first power chip 4A may form part of a low side switch of a half bridge circuit, while the second power chip 4B may form part of a high side switch of the half bridge circuit. An exemplary circuit diagram of a half bridge circuit including a low side switch 42 and a high side switch 44 is shown in FIG. 6C. The first logic chip 10A may be configured to drive the first power chip 4A, and the second logic chip 10B may be configured to drive the second power chip 4B.

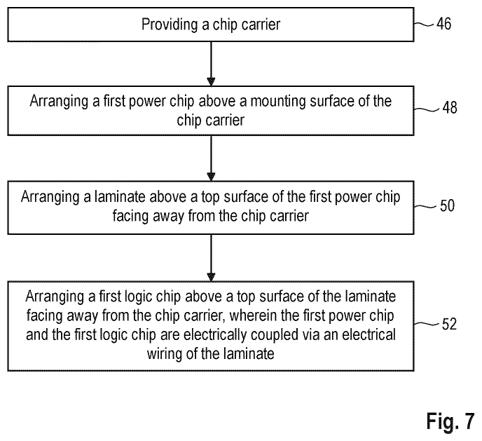

Referring now to FIG. 7, a flowchart of a method in accordance with the disclosure is illustrated. The method is described in a general manner in order to qualitatively specify aspects of the disclosure. The method may be used for manufacturing semiconductor devices in accordance with the disclosure as described herein. The method may be extended by one or more further aspects, for example any of the aspects described in connection with other example discussed herein. It is to be understood that a chronological order of the discussed method steps may be swapped or changed if technically possible and meaningful.

At 46, a chip carrier may be provided. At 48, a first power chip may be arranged above a mounting surface of the chip carrier. At 50, a laminate may be arranged above a top surface of the first power chip facing away from the chip carrier. At 52, a first logic chip may be arranged above a top surface of the laminate facing away from the chip carrier. The first power chip and the first logic chip may be electrically coupled via an electrical wiring of the laminate.

In the following, semiconductor devices in accordance with the disclosure and methods for manufacturing such semiconductor devices are described by means of examples.

Example 1 is a semiconductor device, comprising: a chip carrier; a first power chip arranged above a mounting surface of the chip carrier; a laminate arranged above a top surface of the first power chip facing away from the chip carrier; and a first logic chip configured to drive the first power chip and arranged above a top surface of the laminate facing away from the chip carrier, wherein the first power chip and the first logic chip are electrically coupled via an electrical wiring of the laminate.

Example 2 is a semiconductor device according to Example 1, further comprising: a first electrical coupling element electrically coupling the top surface of the laminate and a first portion of the chip carrier, wherein the first electrical coupling element is electrically coupled to a first electrical contact of the first power chip via the electrical wiring of the laminate.

Example 3 is a semiconductor device according to Example 1 or 2, further comprising: a second electrical coupling element electrically coupling the top surface of the laminate and a second portion of the chip carrier, wherein the second electrical coupling element is electrically coupled to a second electrical contact of the first power chip via the electrical wiring of the laminate.

Example 4 is a semiconductor device according to any of the preceding Examples, further comprising: a third electrical coupling element electrically coupling the top surface of the laminate and a third portion of the chip carrier, wherein the third electrical coupling element is electrically coupled to an electrical contact of the first logic chip via the electrical wiring of the laminate.

Example 5 is a semiconductor device according to Example 1, wherein: the chip carrier is a leadframe comprising a diepad and a plurality of leads, and the first power chip is a power transistor chip.

Example 6 is a semiconductor device according to Example 5, further comprising: a first clip electrically coupling the top surface of the laminate and the diepad, wherein the first clip is electrically coupled to a source contact or an emitter contact of the power transistor chip via the electrical wiring of the laminate.

Example 7 is a semiconductor device according to Example 5 or 6, further comprising: a second clip electrically coupling the top surface of the laminate and a first lead of the plurality of leads, wherein the second clip is electrically coupled to a drain contact or a collector contact of the power transistor chip via the electrical wiring of the laminate.

Example 8 is a semiconductor device according to Example 6 and Example 7, wherein a distance between the source or emitter contact of the power transistor chip and the drain or collector contact of the power transistor chip is smaller than a distance between a first contact point between the first clip and the top surface of the laminate and a second contact point between the second clip and the top surface of the laminate.

Example 9 is a semiconductor device according to any of Examples 5 to 8, further comprising: a wire electrically coupling the top surface of the laminate and a second lead of the plurality of leads, wherein the wire is electrically coupled to the first logic chip via the electrical wiring of the laminate, and wherein the first logic chip is electrically coupled to a gate contact or a base contact of the power transistor chip via the electrical wiring of the laminate.

Example 10 is a semiconductor device according to any of the preceding Examples, wherein the first power chip is a lateral power chip comprising electrical contacts arranged on the top surface of the first power chip.

Example 11 is a semiconductor device according to any of the preceding Examples, wherein an electrical coupling between the first power chip and the first logic chip is provided exclusively via the electrical wiring of the laminate.

Example 12 is a semiconductor device according to any of the preceding Examples, further comprising: a second power chip arranged between the mounting surface of the chip carrier and the bottom surface of the laminate, wherein the second power chip is electrically coupled to the first power chip and to the first logic chip via the electrical wiring of the laminate.

Example 13 is a semiconductor device according to Example 12, wherein the first logic chip is configured to drive the first power chip and the second power chip.

Example 14 is a semiconductor device according to any of Examples 1 to 11, further comprising: a second power chip arranged between the mounting surface of the chip carrier and the bottom surface of the laminate, and a second logic chip arranged above the top surface of the laminate, wherein the second power chip is electrically coupled to the first power chip and to the second logic chip via the electrical wiring of the laminate, and wherein the second logic chip is electrically coupled to the first logic chip via the electrical wiring of the laminate.

Example 15 is a semiconductor device according to Example 14, wherein: the first logic chip is configured to drive the first power chip, and the second logic chip is configured to drive the second power chip.

Example 16 is a semiconductor device according to any of Examples 12 to 15, wherein the first power chip and the second power chip form part of a low side switch and a high side switch of a half bridge circuit.

Example 17 is a semiconductor device according to any of the preceding Examples, wherein a surface of the chip carrier opposite to the mounting surface of the chip carrier is exposed and coplanar with a surface of at least one lead of the chip carrier.

Example 18 is a semiconductor device according to any of the preceding Examples, wherein a surface of the chip carrier opposite to the mounting surface of the chip carrier is exposed and at least one lead of the chip carrier is bent in a direction away from the exposed surface of the chip carrier.

Example 19 is a method for manufacturing a semiconductor device, the method comprising: providing a chip carrier; arranging a first power chip above a mounting surface of the chip carrier; arranging a laminate above a top surface of the first power chip facing away from the chip carrier; and arranging a first logic chip above a top surface of the laminate facing away from the chip carrier, wherein the first power chip and the first logic chip are electrically coupled via an electrical wiring of the laminate.

As employed in this description, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over”, “on”, or the like, used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include a step of providing the component in a suitable manner, even if such step is not explicitly described or illustrated in the figures.

Although the disclosure has been shown and described with respect to one or more implementations, equivalent alterations and modifications will occur to others skilled in the art based at least in part upon a reading and understanding of this description and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

1. Semiconductor device, comprising:
a chip carrier;
a first power chip arranged above a mounting surface of the chip carrier;
a laminate arranged above a top surface of the first power chip facing away from the chip carrier; and
a first logic chip configured to drive the first power chip and arranged above a top surface of the laminate facing away from the chip carrier,
wherein the first power chip and the first logic chip are electrically coupled via an electrical wiring of the laminate.

2. The semiconductor device of claim 1, further comprising:
a first electrical coupling element electrically coupling the top surface of the laminate and a first portion of the chip carrier,
wherein the first electrical coupling element is electrically coupled to a first electrical contact of the first power chip via the electrical wiring of the laminate.

3. The semiconductor device of claim 1, further comprising:
a second electrical coupling element electrically coupling the top surface of the laminate and a second portion of the chip carrier,
wherein the second electrical coupling element is electrically coupled to a second electrical contact of the first power chip via the electrical wiring of the laminate.

4. The semiconductor device of claim 1, further comprising:
a third electrical coupling element electrically coupling the top surface of the laminate and a third portion of the chip carrier,
wherein the third electrical coupling element is electrically coupled to an electrical contact of the first logic chip via the electrical wiring of the laminate.

5. The semiconductor device of claim 1, wherein:
the chip carrier is a leadframe comprising a diepad and a plurality of leads, and
the first power chip is a power transistor chip.

6. The semiconductor device of claim 5, further comprising:
a first clip electrically coupling the top surface of the laminate and the diepad,
wherein the first clip is electrically coupled to a source contact or an emitter contact of the power transistor chip via the electrical wiring of the laminate.

7. The semiconductor device of claim 6, further comprising:
a second clip electrically coupling the top surface of the laminate and a first lead of the plurality of leads,
wherein the second clip is electrically coupled to a drain contact or a collector contact of the power transistor chip via the electrical wiring of the laminate.

8. The semiconductor device of claim 7, wherein a distance between the source or emitter contact of the power transistor chip and the drain or collector contact of the power transistor chip is smaller than a distance between a first contact point between the first clip and the top surface of the laminate and a second contact point between the second clip and the top surface of the laminate.

9. The semiconductor device of claim 5, further comprising:
a wire electrically coupling the top surface of the laminate and a second lead of the plurality of leads,
wherein the wire is electrically coupled to the first logic chip via the electrical wiring of the laminate, and
wherein the first logic chip is electrically coupled to a gate contact or a base contact of the power transistor chip via the electrical wiring of the laminate.

10. The semiconductor device of claim 1, wherein the first power chip is a lateral power chip comprising electrical contacts arranged on the top surface of the first power chip.

11. The semiconductor device of claim 1, wherein an electrical coupling between the first power chip and the first logic chip is provided exclusively via the electrical wiring of the laminate.

12. The semiconductor device of claim 1, further comprising:
a second power chip arranged between the mounting surface of the chip carrier and a bottom surface of the laminate,
wherein the second power chip is electrically coupled to the first power chip and to the first logic chip via the electrical wiring of the laminate.

13. The semiconductor device of claim 12, wherein the first logic chip is configured to drive the first power chip and the second power chip.

14. The semiconductor device of claim 1, further comprising:
a second power chip arranged between the mounting surface of the chip carrier and a bottom surface of the laminate, and
a second logic chip arranged above the top surface of the laminate,
wherein the second power chip is electrically coupled to the first power chip and to the second logic chip via the electrical wiring of the laminate, and
wherein the second logic chip is electrically coupled to the first logic chip via the electrical wiring of the laminate.

15. The semiconductor device of claim 14, wherein:
the first logic chip is configured to drive the first power chip, and
the second logic chip is configured to drive the second power chip.

16. The semiconductor device of claim 12, wherein the first power chip and the second power chip form part of a low side switch and a high side switch of a half bridge circuit.

17. The semiconductor device of claim 1, wherein a surface of the chip carrier opposite to the mounting surface of the chip carrier is exposed and coplanar with a surface of at least one lead of the chip carrier.

18. The semiconductor device of claim 1, wherein a surface of the chip carrier opposite to the mounting surface of the chip carrier is exposed and at least one lead of the chip carrier is bent in a direction away from the exposed surface of the chip carrier.

19. A method for manufacturing a semiconductor device, the method comprising:
providing a chip carrier;
arranging a first power chip above a mounting surface of the chip carrier;
arranging a laminate above a top surface of the first power chip facing away from the chip carrier; and
arranging a first logic chip above a top surface of the laminate facing away from the chip carrier,
wherein the first power chip and the first logic chip are electrically coupled via an electrical wiring of the laminate.
